(19) United States
(12) Patent Application Publication
(10) Pub. No.: US 2026/0208392 A1
(43) Pub. Date: Jul. 23, 2026

(54) Sawing Device for Forming Saw-Cuts into a Semiconductor Product and Method Therefor

(71) Applicant: Besi Netherlands B.V., Duive (NL)

(72) Inventors: Mark Hermans, Arnhem (NL); Sietse Langius, Herwen (NL)

(21) Appl. No.: 19/141,155

(22) PCT Filed: Dec. 14, 2023
(86) PCT No.: PCT/NL2023/050660

§ 371 Date: Jun. 19, 2025

(30) Foreign Application Priority Data
Dec. 20, 2022 (NL) 2033761

(51) Int. Cl. B28D 5/02; H10P 72/00

(52) U.S. Cl. CPC B28D 5/024; H10P 72/0428

(57) ABSTRACT

The present invention relates to a sawing device for forming saw-cuts into a semiconductor product. The sawing device includes: a carrier including a holding surface for holding the semiconductor product, a saw blade comprising a cutting edge, moveable relative to the carrier, a first position sensor for determining the position of a point on a free surface of the semiconductor product held by the carrier relative to said first position sensor, a second position sensor for determining the position of a point on the cutting edge of the saw blade relative to said second position sensor, and control unit linked to the first position sensor and the second position sensor. The control unit is configured for controlling the relative movement of the saw blade and the carrier.

### CROSS-REFERENCE TO RELATED APPLICATIONS

This application is the United States national phase of International Patent Application No. PCT/NL2023/050660 filed Dec. 14, 2023, and claims priority to The Netherlands Patent Application No. 2033761 filed Dec. 20, 2022, the disclosures of which are hereby incorporated by reference in their entireties.

### BACKGROUND OF THE INVENTION

### Field of the Invention

The present invention relates to a sawing device for forming saw-cuts into a semiconductor product. The invention also relates to a method for forming saw-cuts into a semiconductor product.

### Description of Related Art

In the final stages of semiconductor product fabrication, the fabricated integrated circuits (IC) are singulated (diced) to obtain individual IC packages, or dies. Singulation hereby may take place through machining the substrate interconnecting the individual dies with a rotating saw blade, wherein the substrate is commonly formed by a wafer, a lead frame or a board. As part of the machining operation, any packaging material (often an epoxy resin) encapsulating the dies may in a common instance concurrently be separated. In order to minimize the magnitude of the shear forces in the semiconductor product during the sawing operation, it is beneficial to maximize the sawing depth and thereby let the saw blade overshoot the thickness of the IC package as far as there is space available to allow the saw blade to move into behind the semiconductor product. The dimensions of this space are hereby commonly determined by the jig or carrier holding the semiconductor product during the singulation process. It is thus important that the sawing depth can be controlled with great accuracy to on the one hand maximize the sawing depth while on the other hand prevent the saw blade to saw into the jig or other parts of the sawing device.

Alternatively, the saw blade displacement relative to the IC package may be restricted to the thickness of the lead frame and, if present, the packaging material. This limited saw depth is beneficial if singulation of the individual IC packages is desirable while an underlying substrate such as a foil material layer must remain intact to retain the layout of the separated IC packages for further processing. After all, the IC packages remain connected through the foil material layer in this case. As one could understand, meticulous control of the sawing depth is in this case important to prevent cutting into the foil material layer while completely separating the thereto connected IC packages.

In yet another scenario, the machining of the substrate with the saw may (at first instance) be limited to a partial sawing operation wherein the sawing depth is smaller than the thickness of the carrier, thus leading to a groove being formed into the carrier. No separation of individual IC packages takes place in this case (or at least, not initially). The latter described sawing operation sees application in the fabrication of high-reliability IC packages (in particular quad-flat no leads packages) that need solder-wettable flanks to create robust solder joints wherein a solder fillet adheres to the outer edge of the IC package. After the partial sawing operation, the hereby formed grooves are plated with a solderable surface finish. In a following sawing operation, the IC packages are singulated along a line of singulation adjacent to the groove, creating a step feature in the singulation edge that is easily solder-wettable. This ensures proper solder wetting and thus the formation of highly reliable solder joints during later solder attachment of the IC package to a printed circuit board. It additionally allows for automated optical inspection (AOI) of the solder joints. In order to create grooves having a certain depth with great precision, accurate control of the sawing depth is of great importance.

Even before singulation, IC packages in general are relatively small, typically falling within an order of magnitude of several millimetres. Movable parts of singulation machines, such as a carrier and a saw-blade have to be connected to the remainder of the machine by robust connections. Any flexibility of such connections would be detrimental to the precision and accuracy required for making saw-cuts. As a result, the connections usually comprise relatively large thick steel parts, to provide the stability required for making precise and accurate saw cuts. These connections, or machine parts have to be fitted into a relatively small section of the singulation machine, near the carrier, in order for the saw and carrier to interact, and in order to avoid the connection from becoming excessively long, and hence unstable or more flexible.

Patent application WO 2021/167450 A1 discloses a sawing device for forming saw-cuts into a semiconductor product comprising a carrier, a saw blade, a first position sensor, as second position sensor, a reference, and a control unit for controlling the relative movement of the saw blade and the carrier. Making measuring a distance of the first position sensor to the semiconductor product to allow accurate saw-cuts using this sawing device requires measuring at least three distances: A distance from the first position sensor to a surface of the reference, a distance from the second position sensor to a tip of the saw blade, and a distance from the second position sensor to another surface of the reference. The sawing device disclosed in WO 2021/167450 A1 requires a minimum of four measurements prior to making a saw cut.

As IC packages are a mass-produced product, the rate of throughput of singulation machines is important to meet economical constraints. In other words, the time available to saw substrates into dies is limited. Each measurement made prior to sawing requires valuable time that cannot be spend on sawing. Moreover, each additional measurement is likely to require an additional moving component or additional sensor, further complicating the sawing machine and increasing the odds of malfunctioning of the sawing machine, owing to the increased complexity.

### SUMMARY OF THE INVENTION

It is therefore a goal of the present invention to enhance reliability and processing speed at which saw-cuts are formed into a semiconductor product with high accuracy and precision.

The invention hereto provides a sawing device for forming saw-cuts into a semiconductor product as described herein. Within the scope of the present invention, the free surface of the semiconductor product is the surface of the semiconductor product in which the at least one controlled cut is made during the relative movement of the saw blade and the carrier. Said cut(s) may completely separate the semiconductor product into a number of IC packages, but may also form (shallow) grooves in the free surface extending only along a part of the height of the semiconductor product, measured in a direction perpendicular to the free surface. Alternatively, the cut(s) may separate the semiconductor product but leave an underlying foil material layer intact.

The sawing device according to the invention employs two position sensors: one for determining the position of the free surface of the semiconductor product and one for determining the position of the saw blade, and in particular the cutting edge thereof. By actually measuring the position of the free surface of the semiconductor product (or at least a point thereon) and the cutting edge of the saw blade (or at least a point thereon), the least amount of inference is necessary to determine their relative positions, thus minimizing the positional error while relatively moving the carrier with the thereto attached semiconductor product and the saw blade. For example, unevenness of the cutting edge due to wear of the saw blade or height differences in the free surface due to warpage of the semiconductor product can be corrected for due to these measurements. This will enable the sawing device to make a saw-cut with a predetermined depth with high accuracy. The depth of the saw-cut is herein defined as the direction perpendicular to the free surface of the semiconductor product.

By using two position sensors, it becomes easy to observe the cutting edge of the saw blade at the point where the cutting edge contacts the free surface of the semiconductor product together with observing the free surface of the semiconductor product. Namely, as the free surface of the semiconductor product opposes the position on the cutting edge at which the saw blade cuts into said free surface, the use of a single position sensor that relies on a clear line-of-sight between itself and the object to be measured poses practical difficulties. Commonly, a circular saw is used, such that inspection of the cutting edge of the saw blade could in theory also be performed on a side of the saw blade facing away from the free surface of the semiconductor product. However, inspecting the saw blade directly at the actual position of contact eliminates positional errors related to for example the suspension of the saw blade.

The position sensors measure the position of an object relative to themselves. To accurately control the relative movement of the saw blade and the carrier (and thus the thereto connected semiconductor product), necessary for making accurate saw-cuts, the position of the cutting edge of the saw blade and the free surface of the semiconductor product must however be determined relative to each other instead of relative to the position sensors. Namely, this factors out any error in the position of the position sensors.

At the same time, the number of moving components and the number of measurements must be limited to obtain desired robustness of the device, as well as to obtain a fast processing speed. The present invention thereto proposes the use of a reference through which the position of the first position sensor can be linked to the position of the second position sensor. This reference takes the form of a physical object that can either have a position relative to the first position sensor that is obtainable through observation by the first position sensor or that has a position relative to the second position sensor that is obtainable through observation by the second position sensor. The reference has either a position relative to the first position sensor that is fixed via a holder or the reference has a position relative to the second position sensor that is fixed via a holder. Within the scope of the present invention, the reference being fixed to the first position sensor or the second position sensor via a holder means that, in operation, the positions of the reference, first or second position sensor, and the holder are invariable with respect to each other.

The control unit is configured to translate the dimensions and the position of the reference relative to the position sensor capable of observing the reference into a position of the first and second position sensors relative to each other. Together with the positions of the cutting edge of the saw blade, determined by the second position sensor, and the free surface of semiconductor product, determined by the first position sensor, the control unit is then able to determine the position of a point on the free surface of the semiconductor product relative to a point on the cutting edge of the saw blade. As the reference is fixed to either the first position sensor or the second position sensor, measuring a distance between the reference and the corresponding position sensor fixed thereto is not required. As such, the number of measurements required to create accurate and precise saw-cuts in a substrate is reduced. In addition, the number of moving components in the device is reduced. As a result, both processing speed and robustness of the sawing device are enhanced.

In particular, in a configuration wherein the saw blade and the fist position sensor are fixed to each other, and wherein the second position sensor and the reference are fixed to each other, only three measurement are required prior to making a saw cut with high accuracy. A first measurement by the first position sensor measuring a position of the reference, a second measurement by the second position sensor measuring a distance to the tip of the saw blade, and a third measurement by the first position sensor measuring the distance to the surface of the semiconductor product. The first and second measurements can occur simultaneously if a distance of the centre of the saw blade to the first position sensor approximately equals a distance of the second position sensor to the reference, Increasing the processing speed of the sawing device.

In another configuration wherein the saw blade, first position sensor, and the reference are all fixed to each other, also only three measurements are required to make a saw cut. A first measurement by the second position sensor measuring a distance to the tip of the saw blade, a second measurement by the second position sensor measuring a distance to the reference, and a third measurement by the first position sensor measuring a distance to a surface of a semiconductor product held by the carrier.

Advantageously, both configurations only require movement of the saw blade and the first position sensor and optionally the reference, attached thereto, for the sawing device to function. The very limited number of moving parts, together with the limited number of required measurements, ensures that not only the sawing device enables the provision of accurate saw cuts, but also at a high speed.

The positional information obtained from both position sensors is then used for controlling the relative movement of the saw blade and the carrier with high accuracy. Note that position of (the free surface of the) the semiconductor product, and thus also the moment thereof relative to the saw blade, is directly linked to the position of the carrier. Namely, the carrier, also commonly named a jig or a chuck, is configured to grip and hold onto the semiconductor product, for example by suction means, such that the position of the semiconductor product is fixated with respect to the carrier. Control of the relative movement of the saw blade and the carrier thus implies steering of the saw blade with respect to the semiconductor product, determining the position, and in particular the depth of the saw cuts.

The reference is formed by at least one reference surface on the holder observable by the first position sensor or the second position sensor, wherein the first position sensor or the second position sensor is configured for determining the position of a point on the reference surface. The position of the reference surface, or at least a point thereon, may thus be determined by the first position sensor or the second position sensor. The first position sensor or the second position sensor can individually determine the position of said reference surface with respect to itself. Preferably, a distance spanned by the holder between the reference and the first position sensor or the second position sensor is known and invariable.

As the reference is formed by a reference surface fixed to the first position sensor or to the second position sensor via a holder, said reference surface is preferably not located in between the saw blade and the second position sensor, as this will interfere with measuring a point on the cutting edge of the saw blade by the second position sensor.

Preferably, the first position sensor and the second position sensor are not located in between the saw blade and the carrier. The carrier is preferably only movable in a horizontal plane. As a substrate to be cut is held in place by the carrier, at the underside of the carrier, unwanted movement by the carrier towards and away from the saw blade should be prevented. The saw blade, on the other hand, while cutting the substrate, preferably only moves in a direction perpendicular to the horizontal plane, wherein the carrier is movable. This manner of operation contributes to the formation of very accurate saw cuts in the substrate.

Due to the manner of interaction between the carrier and the saw blade, and due to the limited space between saw blade and carrier, it is advantageous that the first position sensor and/or the second position sensor are not placed in between the saw blade and the carrier. In addition, connecting both the first and second position sensor such that a distance spanned by the holder between the first position sensor and the second position sensor is known and invariable, would not be advantageous, as this would necessitate a relatively large movable structure, comprising both position sensors, to be placed in between the carrier and the saw blade. This would further increase the complexity of the sawing device.

The holder may be a first holder, wherein the first position sensor is fixed to the reference via the first holder, wherein a distance spanned by the first holder between the first position sensor and the reference is known and invariable.

Additionally or alternatively, a distance spanned by the first holder between the first position sensor and the saw blade is known and invariable. In this case, the position of the first position sensor relative to the saw blade (and vice versa) can also be determined because the dimensions of the first holder connecting the saw blade and the first position sensor is known.

The holder may also be a second holder, wherein the second position sensor is fixed to the reference via the second holder, wherein a distance spanned by the second holder between the second position sensor and the reference is known and invariable.

The first position sensor and the carrier may be moveable relative to each other. This may enable or simplify mapping the free surface of the semiconductor product with a single position sensor. Connecting thereto, the first position sensor may be configured for determining the position of a plurality of points on the free surface of the semiconductor product. The control unit may in turn be configured to process the position of the plurality of points on the free surface of the semiconductor product into a height profile of said free surface, wherein the control unit is adapted to compensate for said height profile in the control of the relative movement of the saw blade and the carrier. This enables the formation of saw-cuts with a constant depth, defined as the distance from the free surface in a direction perpendicular to said free surface, also if (the free surface of) the semiconductor product is not flat due to e.g. warpage. Given the stringent requirements on the dimensional consistency of the final IC packages, it is important that any warpage of the semiconductor product can be corrected for in the formation of the saw-cuts. This is especially the case for applications of the sawing device wherein the semiconductor product undergoes only a partial sawing operation. A partial sawing operation is herewith defined as an operation wherein the sawing depth is smaller than the thickness of the semiconductor product, including any foil material layers. A partial sawing operation results in a semiconductor product that comprises partial cuts, or grooves in the surface of the semiconductor product. This may include the situation wherein the semiconductor product may be fully singulated into separate IC packages, but wherein an underlying foil material layer remains intact to retain the mutual orientation of said separated IC packages. In the latter instance, the sawing depth must be exactly the same as the local thickness of the semiconductor product excluding the foil material layer.

In an embodiment, preferably, the saw blade and the first position sensor are not moveable relative to each other, and the saw blade and the first position sensor are moveable relative to the carrier and the second position sensor. Optionally, the carrier and the second position sensor are not movable relative to each other. This arrangement of first position sensor, second position sensor, carrier, and saw blade is advantageous, as the number of moving parts is very limited. The moving parts may include the saw blade and the first position sensor, the latter preferably being stationarily connected to the saw blade, and either of the second position sensor and the carrier. The second position sensor and the carrier may movable relative to each other, but the second position sensor and/or the carrier could also be stationarily arranged within the sawing device. As such, the saw blade can perform cuts in a semiconductor product held by the carrier with a high precision, due to the relatively low number of moving parts.

The second position sensor and the saw blade may also be moveable relative to each other. If the saw blade is of the rotary type, the second position sensor and the saw blade are already moveable relative to each other, wherein the second position sensor is able to observe the entire cutting edge of the saw blade. The second position sensor may hereby have a fixed position with respect to the sawing device. It may also be possible that instead of or together with the saw blade, the second position sensor is moveable with respect to the sawing device. The latter case may be beneficial in reducing the movement of the saw blade in the position determination of the cutting edge, which could lead to time gains in the sawing operation, as well as a reduction in the wear and tear on the sawing device. The second position sensor is commonly configured for determining the position of a plurality of points on the cutting edge of the saw blade. This enables the position sensor in co-operation with the control unit to determine the height profile of the cutting edge, which changes under the wear of the saw blade. The second position sensor and the saw blade are preferably mutually positioned such that the cutting edge is observable by the position sensor directly at the position with respect to the suspension of the saw blade where the cutting edge contacts the free surface of the semiconductor product. For example, when the free surface of the semiconductor is oriented downwards, the second position sensor is configured to observe the upmost position along the cutting edge of the saw blade.

In a possible embodiment of the sawing device according to the invention, at least one of the first position sensor and second position sensor is a distance sensor. Said distance sensor is adapted to measure the distance between itself and a given point it is set to observe. The distance sensor may herewith determine a one-dimensional position of said point relative to itself. Control of relative movement of the saw blade and the carrier based on the positions determined by the distance sensors is hereby performed with respect to this dimension. Determination of the distance between the cutting edge of the saw blade and the free surface of the semiconductor product based on the respective measurements of the distances between the first position sensor and the free surface, and the second position sensor and the cutting edge, thus allows for control of the depth up to where the saw blade penetrates the free surface. In a preferred embodiment, the distance sensor is a confocal sensor. The distance sensor may alternatively be formed by a triangulation sensor.

The information gathered with the sawing device according to the present invention may be useful for quality control and/or gathering statistical information.

The present invention further relates to a method for forming saw-cuts into a semiconductor product as described herein. In the processing step, the knowledge about the positions of the first position sensor and second position sensor relative to each other, obtained through the reference, is used to translate the positions of (the points on) the free surface and the cutting edge relative to the respective positions of the sensors into positions of (the points on) the free surface and the cutting edge relative to each other. This highly accurate positional information allows for controlling of the relative movement of the saw blade and the carrier with high precision, leading to accurate saw-cuts into the semiconductor product. The holder and in particular the reference attached thereto is used for the position determination of either the first position sensor or the second position sensor not connected via a holder to the reference. Having one position sensor connected directly and fixedly to the reference substantially enhances accuracy and speed of the saw-cut forming.

The first position sensor may determine the position of a plurality of points on the free surface of the semiconductor product. The plurality of points on the free surface of the semiconductor product may hereby be processed into a height profile of said free surface, for which height profile is compensated for in the movement the saw-blade relative to the carrier. This compensation may have the effect that the height profile of the free surface of the semiconductor product is followed by the cutting edge of the saw blade to obtain a saw-cut with a (more) uniform depth over the saw cut's entire length along the free surface of the semiconductor product, wherein the depth of the saw-cut is again defined as the distance from the free surface in a direction perpendicular to said free surface.

The height profile of the free surface of the semiconductor product may be followed by the cutting edge of the saw blade in a stepwise fashion. This stepwise following of the free surface of the semiconductor product may be attained by adjusting the sawing depth, and thus the distance over which the saw blade penetrates the semiconductor product, for a certain number of times over the length of the saw-cut. The smaller the adjustment interval, the better the saw blade is able to follow the height profile of the free surface semiconductor product, and the smaller the differences will be in the depth of the saw-cut. As the sawing depth is adjusted based on the relative positions of the saw blade and the semiconductor product, determined by the position sensors,, the number of adjustments typically does not exceed the measurement resolution, being the number of points on the free surface of the semiconductor product for which the position is determined by the first position sensor.

The height profile of the free surface of the semiconductor product may alternatively be followed by the cutting edge of the saw blade in a continuous fashion. For instance, the saw blade may be moved along a straight line during the formation of (part of) the saw-cut. As a result, the saw-cut will have a gradual progression that will not be able follow local height differences in the free surface as much as it is able to follow a global height gradient which is commonly seen as a result of warpage of the semiconductor product. The trajectory followed by the saw blade is commonly determined by drawing a straight line between two points on the free surface of the semiconductor product and cutting into the free surface at a constant cutting depth with respect to said straight line.

Alternatively, the trajectory followed by the saw blade may be determined by fitting a profile onto distance measurements of multiple points on the free surface of the semiconductor product. The following of the free surface of the semiconductor product is in this case obtained by adjusting the sawing depth, and thus the distance over which the saw blade penetrates the semiconductor product based on the fitted profile. As such, the height profile of the free surface of the semiconductor product is followed by the cutting edge of the saw blade in a continuous fashion.

The position of a point on the cutting edge of the saw blade may be determined before the formation of every consecutive saw-cut. During each sawing operation, the saw blade will abrade. To factor in this abrasion in the formation of the subsequent saw-cuts, it is necessary to measure the position of the cutting edge before the start of the following sawing operation. In practice, the position of multiple points along the entire cutting edge of the saw blade are determined, such that the wear of the entire cutting edge can be mapped and corrected for in the relative movement of the saw blade and the carrier and thus the formation of the saw-cuts.

As an even more accurate way of correcting for wear of the cutting edge of the saw blade, the position of a point on the cutting edge may be determined before and after the formation of a saw-cut, wherein the difference in the position of said point on the cutting edge before and after the formation of a saw-cut is used as feed forward information in controlling the relative movement of the saw-blade and the carrier in the formation of a consecutive saw-cut. The movement of the saw blade and the carrier is hereby corrected for the expected abrasion of the cutting edge by means of extrapolation. It thus possible to use the measured actual depths of the saw-cuts as additional input in the feedback steering of subsequent saw-cuts to be sawed.

The sawn semiconductor product may be subjected to a control measurement wherein the positions of the saw-cuts are registered. In the registration of the position of the saw-cuts, at least one of a saw-cut depth, measured at a right angle to the free surface of the semiconductor product, and a saw-cut offset, measured in a plane of the free surface of the semiconductor product, may be determined. The results of such a post-measurement may form input for future sawing operations. Systematic errors in the position of the saw-cuts and therefore the position of the point on the free surface of the semiconductor product relative to the point on the cutting edge of the saw blade can herewith be detected and corrected for.

### BRIEF DESCRIPTION OF THE DRAWINGS

The terms FIG., FIGS., Figure, and Figures are used interchangeably in the specification to refer to the corresponding figures in the drawings.

The present invention will be further elucidated on the basis of the non-limitative exemplary embodiments, shown in the following figures, wherein:

FIG. 1 shows a schematic representation of an embodiment of the sawing device according to the invention, and

FIG. 2 shows a schematic representation of another embodiment of the sawing device according to the invention.

### DESCRIPTION OF THE INVENTION

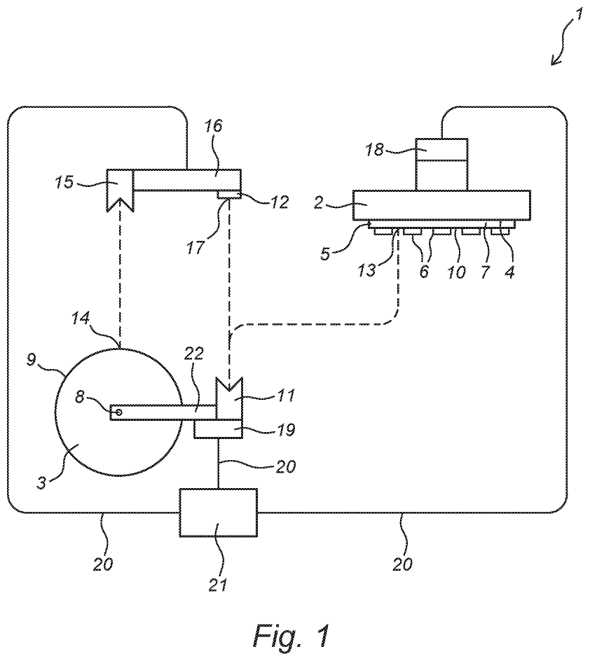

In the schematic representation of FIG. 1, a sawing device 1 is shown, comprising a carrier 2, otherwise denoted as a chuck or jig, and a saw blade 3. The carrier 2 comprises a holding surface 4 for holding a semiconductor product 5. The holding surface 4 may for example be provided with suction means or clamping means for keeping the semiconductor product 5 stationary with respect to the carrier 2. The semiconductor product 5 may be formed by a number of electrical components 6 (dies) mounted on a wafer, a lead frame, a board or any other form of substrate 7. The saw blade 3 in the present example is of the rotary type and rotatable around a suspension axis 8. The outer periphery of the saw blade 3 is formed by the cutting edge 9 which contacts and therewith cuts into the semiconductor product 5 during the cutting operation. The carrier 2 and the saw blade 3 are moveable relative to each other. Commonly, the sawing device 1 is configured such that the second position sensor 15 is held in a stationary position and the carrier 2 positions the substrate 7 by moving at least a single direction (direction x). During operation the saw blade 3 is movable in at least one direction z, perpendicular to direction x. The interaction between movement of the carrier 2 and movement of the saw blade 3 enables sawing of the substrate 7.

A free surface 10 of the semiconductor product 5, facing away from the carrier 2, can be observed by a first position sensor 11 by moving the carrier over the first position sensor. In FIG. 1, the first position sensor 11 is observing a reference 12. In this particular instance, the first position sensor 11 is formed by a distance sensor, capable of determining the distance between itself and a point 13 on the free surface 10 of the semiconductor product 5, thereby essentially determining the position of said point 13 on the free surface 10 in the in a single dimension. The cutting edge 9 of the saw blade 3, and in particular a point 14 on the cutting edge 9 facing (in this case) upwards towards the free surface 10 of the semiconductor product 5, is observed by a second position sensor 15. Like the first position sensor 11, the second position sensor 15 is formed by a distance sensor, capable of determining the distance between itself and a point 14 on the cutting edge 9 of the saw blade 3.

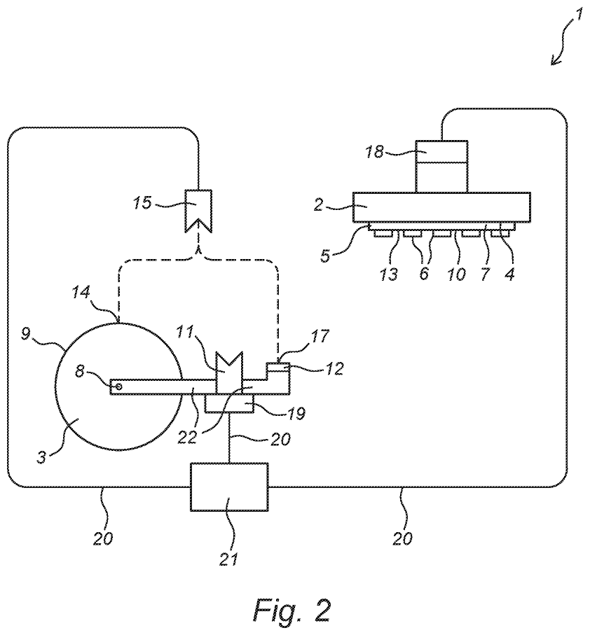

In FIGS. 1 and 2, the observation of the point 13, the reference surface 17, and the cutting edge 14 is indicated by dashed lines. Where the dashed lines are not straight, a movement of the carrier 2 and/or the saw blade 3 relative to the second position sensor 15, is required prior to the observation. The dashed lines are thus examples of possible observations by the position sensors 11, 15.

In FIG. 1, the second position sensor 15 is connected to the reference 12 via a second holder 16. The distance between the second position sensor 15 and the reference 12 is known and invariable. As such, the exact position of the reference 12 with respect to the second position sensor 15 is determined by the shape and size of the second holder 16.

The reference 12, and in particular the reference surface 17 of the reference 12 is detectable by the first position sensor 11 through moving the reference 12 and the first position sensor 11 relative to each other. The second holder 16 can be shaped such that it fits within the limited space available within the sawing device 1. Although both the reference 12 and the second position sensor 15 are invariable with respect to each other during operation of the sawing device 1, they may be replaced by a new reference 12 or second position sensor 15 in case of a malfunctioning reference 12, second position sensor 15 or any part of the second holder 16 itself. Therefore, the second holder 16 may provide accommodating spaces for both the reference 12 as well as the second position sensor 15 to be locked into its position.

The position sensors 11, 15 and the drives 18, 19 responsible for moving the carrier 2 and the saw blade 3 with respect to the second position sensor 15 are (via data link connections 20) connected to a control unit 21. Data originating from the position sensors 11, 15 is via the connections 20 with the control unit 21 sent to said control unit 21 to process said data into a position of the free surface 10 of the semiconductor product 5 relative to the cutting edge 9 of the saw blade 3.

In FIG. 1, a first holder 22 connects the saw blade 3 and the first position sensor 11. The distance between the saw blade 3 and the first position sensor is thus known and fixed by the first holder 22. During operation, the control unit 21 is further configured to control the drives 18, 19 responsible for relatively moving the carrier 2 and the saw blade 3 and thereby controlling the relative movement of the saw blade 3 and the carrier 2 based on said information on the position of the free surface 10 of the semiconductor product 5 relative to the cutting edge 9 of the saw blade 3. The control unit 21 may be formed by any type of suitable processing means and may comprise multiple modules that may be placed in physically separated locations.

In FIG. 1, the first holder 22, connecting the saw blade 3 and the first position sensor 11, fixes the position of the saw blade 3 and the first position sensor 11 with respect to each other. Likewise, the second holder 16, connecting the reference 12 and the second position sensor 15, fixes the position of the second position sensor 15 and reference surface 12 with respect to each other. As the position of reference 12 and the position of the second position sensor 15 relative to each other are already known, as well as the positions of the saw blade 3 and first position sensor 11 relative to each other, the number of measurements required for each sawing operation is reduced. In addition, valuable space within the sawing device 1 is optimally used, and the complexity of the sawing device 1 is reduced.

The sawing device 1 benefits from being able to measure the position of the cutting edge 14 of the saw blade 3 by the second position sensor 15, thereby allowing adjustment of positioning of carrier 2 relative to the saw blade 3. If the size of the saw blade 3 has been reduced due to wear, a measurement of the cutting edge 14 of the saw blade 3 reflects this, and positioning of the carrier 2 relative to the cutting edge 14 can be appropriately adjusted. In addition, adjusting positioning of the carrier 2 relative to the sawing device 3 due to small curvatures or variances in height uniformity of the substrate 5 is possible due to the measurements of the surface 10 of the substrate 5 by the first position sensor 11.

FIG. 2 shows a schematic representation of another sawing device 1 according to the present invention. The second holder 22 in this embodiment connects not only the saw blade 3 and the first position sensor 11, but also the reference 12. Unlike in FIG. 1, the reference 12 is in the embodiment of FIG. 2 not connected to the second position sensor 15, and the second holder 16 is absent. The process of measuring the distance between the second position sensor 15 and the surface 17 of the reference 12, preferably takes place before the determination of a point 13 on the free surface 10 of the semiconductor product 5. As the reference 12 of the embodiment as shown in FIG. 2 is not connected to the second position sensor 15, the structure containing the second position sensor 15 is less bulky, thereby saving space within the sawing device. In addition, the complexity of the sawing device 1 is further reduced by connecting the saw blade 3, first position sensor 11, and the reference 12 together via the first holder 22.

1. A sawing device for forming saw-cuts into a semiconductor product, comprising:
a carrier comprising a holding surface for holding the semiconductor product,
a saw blade comprising a cutting edge, moveable relative to the carrier,
a first position sensor for determining the position of a point on a free surface of the semiconductor product held by the carrier relative to said first position sensor,
a second position sensor for determining the position of a point on the cutting edge of the saw blade relative to said second position sensor, and
a control unit linked to the first position sensor and the second position sensor, which control unit is configured for controlling the relative movement of the saw blade and the carrier,
wherein the sawing device further comprises a reference for linking the position of the first position sensor to the position of the second position sensor; wherein the reference is fixed to the first position sensor or to the second position sensor via a holder; and
wherein the control unit is configured to:
process, with aid of the reference, the positions determined by the first position sensor and the second position sensor into a position of the point on the free surface of the semiconductor product relative to the point on the cutting edge of the saw blade, and
control the relative movement of the saw blade and the carrier based on said position of the point on the free surface of the semiconductor product relative to the point on the cutting edge of the saw blade, and
wherein the reference is formed by a reference surface on the holder observable by the first position sensor or the second position sensor, wherein the first position sensor or the second position sensor is configured for determining the position of a point on the reference surface, and
wherein a distance spanned by the holder between the reference and the first position sensor or the second position sensor is known and invariable. ;

2. The sawing device according to claim 1, wherein the holder is a first holder, wherein the first position sensor is fixed to the reference via the first holder, wherein a distance spanned by the first holder between the first position sensor and the reference is known and invariable.

3. The sawing device according to claim 2, wherein a distance spanned by the first holder between the first position sensor and the saw blade is known and invariable.

4. The sawing device according to claim 1, wherein the holder is a second holder, wherein the second position sensor is fixed to the reference via the second holder, wherein a distance spanned by the second holder between the second position sensor and the reference is known and invariable.

5. The sawing device according to claim 1, wherein the first position sensor and the carrier are moveable relative to each other.

6. The sawing device according to claim 1, wherein the second position sensor and the saw blade are moveable relative to each other.

7. The sawing device according to claim 1, wherein the saw blade and the first position sensor are not moveable relative to each other, and the saw blade and the first position sensor are moveable relative to the carrier and the second position sensor.

8. The sawing device according to claim 1, wherein the first position sensor is configured for determining the position of a plurality of points on the free surface of the semiconductor product.

9. The sawing device according to claim 8, wherein the control unit is configured to process the position of the plurality of points on the free surface of the semiconductor product into a height profile of said free surface, wherein the control unit is adapted to compensate for said height profile in the control of the relative movement of the saw blade and the carrier.

10. (canceled)

11. (canceled)

12. A method for forming saw-cuts into a semiconductor product, comprising the steps of:
gripping a semiconductor product with a carrier,
determining with a first position sensor the position of a point on a free surface of the semiconductor product,
determining with a second position sensor the position of a point on a cutting edge of a saw blade,
using a reference to link the position of the first position sensor to the position of the second position sensor,
processing, with aid of the reference, the positions determined by the first position sensor and the second position sensor into a position of the point on the free surface of the semiconductor product relative to the point on the cutting edge of the saw blade, and
moving the saw-blade relative to the carrier based on the position of the cutting edge of the saw blade relative to the bottom surface of the semiconductor product, thereby cutting into the free surface of the semiconductor product,
wherein the reference to link the position of the first position sensor to the position of the second position sensor is determined by a reference surface that is observed by the first position sensor or the second position sensor,
wherein a distance between the reference and the first position sensor is known and invariable or wherein a distance between the reference and the second position sensor is known and invariable, and
wherein the first position sensor and/or the second position sensor determines the position of a point in relation to the reference surface.

13. (canceled)

14. The method according to claim 12, wherein the plurality of points on the free surface of the semiconductor product are processed into a height profile of said free surface, for which height profile is compensated for in the movement the saw-blade relative to the carrier.

15. The method according to claim 14, wherein the height profile of the free surface of the semiconductor product is followed by the cutting edge of the saw blade in a continuous fashion.

16. The method according to claim 12, wherein the position of a point on the cutting edge of the saw blade is determined before and after the formation of a saw-cut, wherein the difference in the position of said point on the cutting edge before and after the formation of a saw-cut is used as feed forward information in controlling the relative movement of the saw-blade and the carrier in the formation of a consecutive saw-cut.

17. The method according to claim 12, wherein the sawn semiconductor product is subjected to a control measurement wherein the depths and positions-of the saw-cuts are registered.

18. The method according to claim 17, wherein in the registration of the position of the saw-cuts, at least one of a saw-cut depth, measured at a right angle to the free surface of the semiconductor product, and a saw-cut offset, measured in a plane of the free surface of the semiconductor product, is determined.
